(19) United States
(12) Patent Application Publication
(10) Pub. No.: US 2025/0331334 A1
(43) Pub. Date: Oct. 23, 2025

(54) A LIGHT EMITTING DEVICE ON GE

(71) Applicant: IQE PLC, St. Mellons, Cardiff (GB)

(72) Inventors: Andrew JOHNSON, St. Mellons, Cardiff (GB); Hugues MARCHAND, St. Mellons, Cardiff (GB); Sung Wook LIM, St. Mellons, Cardiff (GB)

(21) Appl. No.: 19/108,594

(22) PCT Filed: Sep. 4, 2023
(86) PCT No.: PCT/EP2023/074146

§ 371 Date: Mar. 4, 2025

(30) Foreign Application Priority Data
Sep. 12, 2022 (GB) 2213280.7

(51) Int. Cl. H10H 20/815; H01S 5/183; H01S 5/30; H01S 5/40; H10H 20/01; H10H 20/814; H10H 20/824

(52) U.S. Cl. CPC H10H 20/815; H01S 5/3013; H10H 20/013; H10H 20/8142; H10H 20/824; H01S 5/18361; H01S 5/4031; H01S 2304/02; H01S 2304/04

(57) ABSTRACT

A light emitting device comprising a germanium first layer; a nucleation layer; a buffer layer comprising a III-V composition; and an active layer. The sum product of As concentration and layer thickness in each of the layers is less than 20%. This enables the devices to be fabricated in an environment which must be free, or substantially free, of arsenic.

A light emitting device, particularly but not exclusively a resonant cavity LED, which is formed on germanium.

Typically light emitting devices have been fabricated by forming a gallium arsenide (GaAs) buffer layer on a GaAs substrate, followed by forming additional layers to implement functional elements such as optical mirrors, light-emitting region, and cladding regions. The additional layers typically consist of GaAs and aluminium gallium arsenide (AlGaAs) for mirrors and AlGaAs or indium gallium aluminium phosphide (InGaAlP) for the light emitting region and cladding regions, according to the desired emission wavelength. Such devices are useful for lighting applications and for large display applications. GaAs substrates are widely available but tend to be expensive and are limited in diameter, resulting in a relatively high fabrication cost.

Light emitting devices have also been fabricated on germanium (Ge) substrates, by growing a GaAs buffer layer on germanium. This approach makes use of the fortuitous lattice match of GaAs relative to germanium, which enables the growth of GaAs layers of quality suitable for device applications directly on a germanium substrate. The additional device layers are then formed on the GaAs buffer layer, in the same manner as on GaAs substrates. Whilst these devices can be fabricated in factories designed for III-V compound processing, the use of arsenic in such layer stacks presents a contamination risk in factories that are designed for the fabrication of silicon-based devices, since arsenic is an impurity in silicon and can result in performance or reliability degradation for the silicon processes. This risk prevents the adoption of large-scale silicon-based factories to fabricate devices on 200 mm and 300 mm Ge.

The present invention seeks to address this disadvantage.

The present invention provides a light emitting device comprising: a germanium first layer; a nucleation layer; a buffer layer comprising a III-V composition; and an active layer; wherein the sum product of arsenic concentration and layer thickness in each of the layers is less than 20%.

Minimising and controlling the amount of arsenic in the device is advantageous because it enables the device to be fabricated in an environment which must be free, or substantially free, of arsenic. For example, environments in which Group IV semiconductors are normally fabricated are sensitive to arsenic which is a dopant for Group IV layers such as those containing silicon. Advantageously such fabrication environments are arranged for large-scale manufacture with the consequent economies of scale and cost advantages.

Advantageously germanium substrates are available in large diameter wafers which are mechanically more robust than equivalent gallium arsenide wafers. Thus a thinner substrate can be used, or the substrate can be thinned further in subsequent manufacturing steps, without affecting the integrity of the devices grown on the wafer. For example, germanium wafers are readily available in 200 mm, 300 mm and larger diameter wafers which are larger than are available for GaAs, which may reduce the device fabrication cost on a per device basis. Larger substrate diameters also enable the fabrication of cost effective large emitter arrays on a single wafer, such as may be required for novel display applications. Advantageously fabrication environments which handle silicon-based devices are easily able to handle germanium-based devices since Si and Ge are both group IV elements with similar properties. Advantageously such fabrication environments are often set up to handle larger diameter wafers.

The light emitting device may be configured to emit light with a wavelength between 570 nm and 1000 nm. Advantageously such a light emitting device can be configured for green through to infrared light emission to suit the particular application contemplated. Advantageously by using the germanium first layer, for example a germanium substrate, similar light emitting devices can be grown as have been grown on gallium arsenide (and therefore can be designed to emit at any desirable wavelength) but with a lower or zero arsenic content.

The light emitting device may comprise a resonant cavity light emitting diode or a resonant cavity micro-light emitting diode.

The sum product may be less than 15%. Advantageously this means the arsenic content is low and controlled whilst enabling some flexibility in the design of the device. For example, in a resonant cavity light emitting diode (RC-LED) a top portion of the device may be arsenic free in order to enable etching of specific layers without contamination, for example etching of the top mirror region without exposing process equipment to by-products containing arsenic. The sum product may be less than 10%. This equates to the equivalent of around 200 nm of arsenic in an edge emitting laser. In an RC-LED additional portions of the device may be free of arsenic, including the light emitting region, which enables deeper etching through the light emitting region without generating by-products which contain arsenic. The sum product may be less than 5%. This equates to the equivalent of around 200 nm of arsenic in a thick LED. In an RC-LED most of the device stack is free of arsenic such that the majority of fabrication steps can be performed without generating by-products containing arsenic.

The sum product may be less than 2%. Advantageously this is low enough to meet very stringent arsenic controls in fabrication environments. This equates to the equivalent of around 200 nm of arsenic in a vertical cavity surface emitting laser (VCSEL). Avoiding layers containing arsenic also results in fewer interfaces between layers containing arsenic and layers containing phosphorus. This is advantageous since such interfaces can degrade device performance or reliability due to interface strain or roughness.

The buffer layer may comprise a first sublayer adjacent the nucleation layer and a second sublayer. The first sublayer may comprise a III-V composition. The second sublayer may comprise a different III-V composition. The first sublayer and second sublayer of the buffer layer may be arranged so that one has a tensile strain and the other has a compressive strain. Advantageously the resultant strain is minimal.

The first sublayer and second sublayer of the buffer layer may comprise the same material and/or the same composition. The first sublayer and second sublayer of the buffer layer may comprise the same material with the same composition. They may be grown under different conditions and/or have another difference such as differing doping levels. Advantageously this is simple to grow because the same sources are used and other growth parameters are controlled. The first sublayer and second sublayer of the buffer layer may comprise the same material with different composition. Advantageously this is simple to grow because the same sources are used and the proportions are varied between the sublayers. Alternatively the first sublayer and second sublayer of the buffer layer may comprise the same composition but may have another difference, for example doping levels or growth conditions. Advantageously this is also simple to grow because the same sources are used and other growth parameters are controlled.

There may be more than two sublayers forming the buffer layer. One or more sublayer may be graded in composition and/or dopant level.

The first sublayer may comprise indium gallium phosphide. Advantageously this does not include any arsenic meaning it does not increase the total arsenide content of the light emitting device. The first sublayer may comprise indium aluminium phosphide. Advantageously this does not include any arsenic meaning it does not increase the total arsenide content of the light emitting device. The first sublayer may comprise indium gallium arsenide. Although this contains some arsenic the composition and/or thickness may be set to minimise or limit the amount of arsenide so that the total arsenide content in the light emitting device is within the defined limit for the fabrication environment.

The second sublayer may comprise gallium arsenide. The second sublayer may be thin so that the total arsenide content of the light emitting device does not exceed the defined limit. The second sublayer may comprise indium gallium phosphide. Advantageously this comprises no arsenic.

The light emitting device may comprise a lower mirror. The lower mirror may comprise a III-V material composition without arsenic. Advantageously the lower mirror does not contribute to the total arsenic content in the device and therefore may be as thick as appropriate for the optical or other properties of the device.

The lower mirror may comprise an alternating stack of indium aluminium phosphide and indium aluminium gallium phosphide sublayers. Advantageously the lower mirror does not contribute to the total arsenic content in the device and therefore there may be as many alternating sublayers in the stack as appropriate for the optical or other properties of the device.

The light emitting device may comprise a lower cladding layer between the first layer and the active layer. The lower cladding layer may provide confinement of the optical mode. It may also function to inject carriers into the active region, which may be in conjunction with an upper cladding layer. The lower cladding layer may also or alternatively function to space the active region from the first layer and/or optional lower mirror at an optimum distance. The lower cladding layer may comprise indium aluminium phosphide or indium aluminium gallium phosphide. Advantageously the lower cladding layer does not contribute to the total arsenic content of the device.

The light emitting device may comprise an upper mirror. The upper mirror may comprise a III-V material composition without arsenic. Advantageously the upper mirror does not contribute to the total arsenic content in the device and therefore may be as thick as appropriate for the optical or other properties of the device.

The upper mirror may comprise an alternating stack of indium aluminium phosphide and indium aluminium gallium phosphide sublayers. Advantageously the upper mirror does not contribute to the total arsenic content in the device and therefore there may be as many alternating sublayers in the stack as appropriate for the optical or other properties of the device.

The light emitting device may comprise an upper cladding layer between the active layer and the upper mirror. The upper cladding layer may provide confinement of the optical mode. It may also function to inject carriers into the active region, which may be in conjunction with a lower cladding layer. The upper cladding layer may also or alternatively function to space the active region from the active layer and/or optional upper mirror at an optimum distance. The upper cladding layer may comprise indium gallium phosphide or indium gallium aluminium phosphide. Advantageously the upper cladding layer does not contribute to the total arsenic content of the device.

The active layer may comprise indium gallium phosphide or indium gallium aluminium phosphide. Advantageously the active layer does not contribute to the total arsenic content of the device.

The first layer may comprise germanium with a large miscut from a major crystal plane. For example it may comprise Ge (100) miscut towards the <111> plane. Advantageously this provides an easier surface to grow III-V compounds on, and is common in the industry thus it is cheaper, readily available in large diameters and the characterisation methods/expected patterns are well understood. The first layer may be germanium miscut by up to 15° from a major crystal plane. The first layer may be germanium miscut by up to 10° from a major crystal plane. The first layer may be germanium miscut by up to 6° from a major crystal plane. The first layer may be germanium miscut by up to 3° from a major crystal plane. Advantageously a miscut germanium first layer precludes the formation of antiphase domains in layers grown it.

The first layer may be a substrate miscut by up to 15° from a major crystal plane. The first layer may be a substrate miscut by up to 10° from a major crystal plane. The first layer may be a substrate miscut by up to 6° from a major crystal plane. The first layer may be a substrate miscut by up to 3° from a major crystal plane. For example the first layer may be Ge (100) miscut towards the <111> plane. Advantageously a miscut substrate precludes the formation of antiphase domains in layers grown over the substrate.

The nucleation layer may comprise indium gallium phosphide. Advantageously the nucleation layer does not contribute to the total arsenic content of the device.

At least one of the buffer layer, lower mirror, and upper mirror may be doped. Any one or more of those layers may be n-doped or p-doped. Advantageously this improves the electrical conductivity of the layer. The choice of doping type may be dictated by the device design.

The light emitting device may be an edge emitting laser. The light emitting device may be an LED. The light emitting device may be a micro-LED. The light emitting device may be a resonant cavity LED. The light emitting device may be a VCSEL. The light emitting device may be an LED combined with a photodetector. The light emitting device may be a resonant cavity LED combined with a photodetector. The light emitting device may be a micro-LED combined with a photodetector. Advantageously any type of light emitting device can comprise a germanium first layer and have a low total arsenic content so that it is suitable for fabrication in an environment which is sensitive to arsenic, such as a group IV fabrication environment.

The present invention also provides a method of fabricating a light emitting device comprising steps to: grow a nucleation layer on a germanium first layer; grow a buffer layer on the nucleation layer; and grow an active layer; wherein there is less than 20% arsenic in the light emitting device calculated as the sum product of the arsenic concentration in a layer and the thickness of the layer. Advantageously the steps of the method can be designed and controlled to achieve the low total arsenic content making the method and resultant device suitable for fabrication and further processing in an environment, such as a group IV fabrication environment, which is sensitive to arsenic. Advantageously the growth steps for low arsenic devices can be performed in a similar manner to the growth steps for conventional high arsenic devices. Thus the steps are well established and repeatable growth steps, for example epitaxial growth steps, which result in high quality layers.

The steps may comprise growing layers using metal-organic vapour phase epitaxy, metal-organic chemical vapour deposition, or molecular beam epitaxy.

The present invention will be more fully described by way of example with reference to the accompanying drawings, in which:

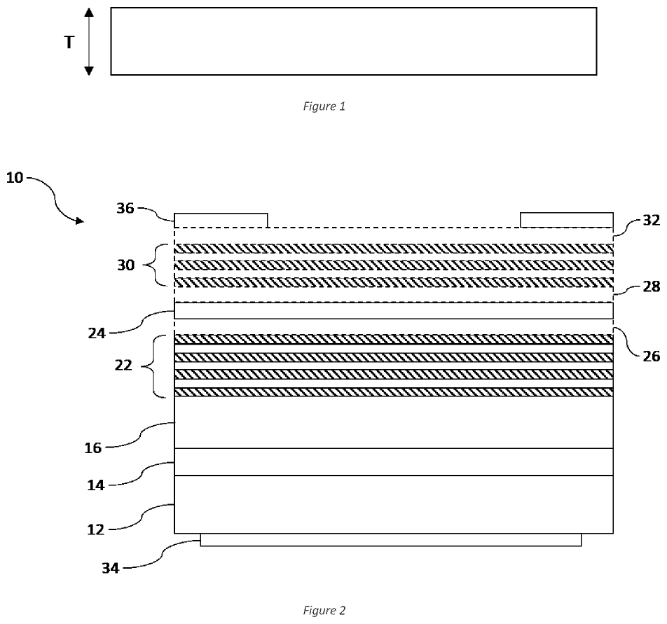

FIG. 1 is a schematic cross-section of a layer;

FIG. 2 is a schematic cross-section of a resonant cavity light emitting diode according to the present invention;

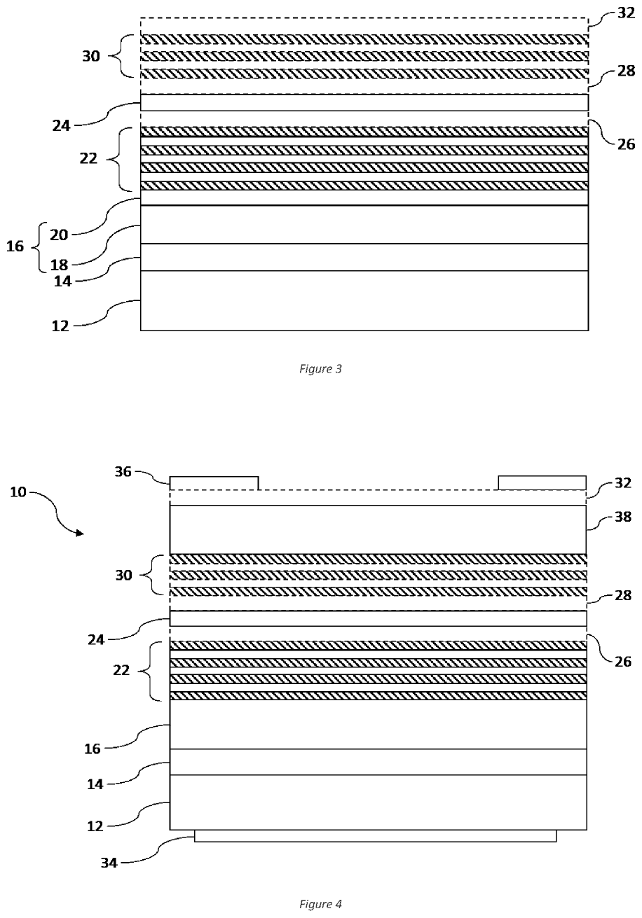

FIG. 3 is a schematic cross-section of a resonant cavity light emitting diode according to the present invention;

FIG. 4 is a schematic cross-section of a resonant cavity light emitting diode according to the present invention;

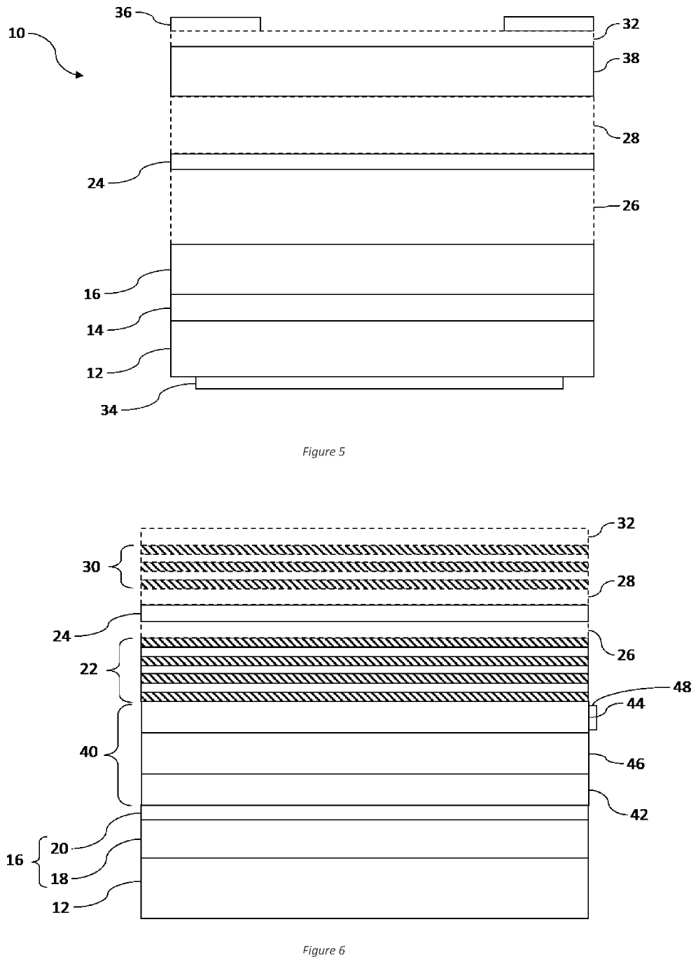

FIG. 5 is a schematic cross-section of a resonant cavity light emitting diode according to the present invention;

FIG. 6 is a schematic cross-section of a combined light emitting diode and PIN diode according to the present invention;

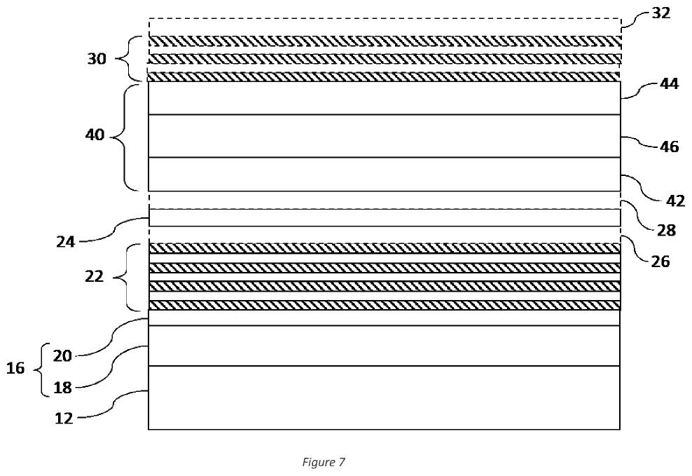

FIG. 7 is a schematic cross-section of a combined light emitting diode and PIN diode according to the present invention;

Epitaxy or epitaxial means crystalline growth of material, usually via high temperature deposition. Epitaxy can be effected in a molecular beam epitaxy (MBE) tool in which layers are grown on a heated substrate in an ultra-high vacuum environment. Elemental sources are heated in a furnace and directed towards the substrate without carrier gases. The elemental constituents react at the substrate surface to create a deposited layer. Each layer is allowed to reach its lowest energy state before the next layer is grown so that bonds are formed between the layers. Epitaxy can also be performed in a metal-organic vapour phase epitaxy (MOVPE) tool, also known as a metal-organic chemical vapour deposition (MOCVD) tool. Compound metal-organic and hydride sources are flowed over a heated surface using a carrier gas, typically hydrogen. Epitaxial deposition occurs at much higher pressure than in an MBE tool. The compound constituents are cracked in the gas phase and then reacted at the surface to grow layers of desired composition, doping and thickness.

Deposition means the depositing of a layer on another layer or substrate. It encompasses epitaxy, chemical vapour deposition (CVD), powder bed deposition and other known techniques to deposit material in a layer.

A compound material comprising one or more materials from group III of the periodic table with one or more materials from group V is known as a III-V material. The compounds have a 1:1 combination of group III and group V regardless of the number of elements from each group. Subscripts in chemical symbols of compounds refer to the proportion of that element within that group. Thus Al_{0.25}GaAs means the group III part comprises 25% Al, and thus 75% Ga, whilst the group V part comprises 100% As.

Crystalline means a material or layer with a single crystal orientation. In epitaxial growth or deposition subsequent layers with the same or similar lattice constant follow the registry of the previous crystalline layer and therefore grow with the same crystal orientation. In-plane is used herein to mean parallel to the surface of the substrate; out-of-plane is used to mean perpendicular to the surface of the substrate.

Throughout this disclosure, as will be understood by the skilled reader, crystal orientation <100> means the face of a cubic crystal structure and encompasses [100], and orientations using the Miller indices. Similarly <0001> encompasses and [000-1] except if the material polarity is critical. Integer multiples of any one or more of the indices are equivalent to the unitary version of the index. For example, (222) is equivalent to, the same as, (111).

Substrate means a planar wafer on which subsequent layers may be deposited or grown. A substrate may be formed of a single element or a compound material, and may be doped or undoped. For example, common substrates include silicon (Si), gallium arsenide (GaAs), silicon germanium (SiGe), silicon germanium tin (SiGeSn), indium phosphide (InP), and gallium antimonide (GaSb).

A substrate may be on-axis, that is where the growth surface aligns with a crystal plane. For example it has <100> crystal orientation. References herein to a substrate in a given orientation also encompass a substrate which is miscut by up to 20° towards another crystallographic direction, for example a (100) substrate miscut towards the (111) plane.

Vertical or out of plane means in the growth direction; lateral or in-plane means parallel to the substrate surface and perpendicular to the growth direction.

Doping means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type whilst a doped material with extra holes (fewer electrons) is called p-type.

Lattice matched means that two crystalline layers have the same, or similar, lattice spacing and so the second layer will tend to grow isomorphically on the first layer. Lattice constant is the unstrained lattice spacing of the crystalline unit cell. Lattice coincident means that a crystalline layer has a lattice constant which is, or is close to, an integer multiple of the previous layer so that the atoms can be in registry with the previous layer. Lattice mismatch is where the lattice constants of two adjacent layers are neither lattice matched nor lattice coincident. Such mismatch introduces elastic strain into the structure, particularly the second layer, as the second layer adopts the in-plane lattice spacing of the first layer. The strain is compressive where the second layer has a larger lattice constant and tensile where the second layer has a smaller lattice constant.

Where the strain is too great the structure relaxes to minimise energy through defect generation, typically dislocations, known as slip, or additional interstitial bonds, each of which allows the layer to revert towards its lattice constant. The strain may be too great due to a large lattice mismatch or due to an accumulation of small mismatches over many layers. A relaxed layer is known as metamorphic, incoherent, incommensurate or relaxed, which terms are also commonly interchangeable.

A pseudomorphic system is one in which a single-crystal thin layer overlies a single-crystal substrate and where the layer and substrate have similar crystal structures and nearly identical lattice constants. In a pseudomorphic structure the in-plane lattice spacing of the thin layer adopts the in-plane lattice constant of the substrate and is therefore elastically strained, either compressively where the layer has a larger lattice spacing than the substrate or tensilely where the layer has a smaller lattice spacing than the substrate. A pseudomorphic structure is not constrained in the out-of-plane direction and so the lattice spacing of the thin layer in this direction may change to accommodate the strain generated by the mismatch between lattice spacing. The thin layer may alternatively be described as “coherent”, “commensurate”, “strained” or “unrelaxed”, which terms are often used interchangeably. In a pseudomorphic structure all the layers adopt the lattice spacing of the substrate in their respective in-plane lattice spacing.

A layer may be monolithic, that is comprising bulk material throughout. Alternatively it may be porous for some or all of its thickness. A porous layer includes air or vacuum pores, with the porosity defined as the proportion of the area which is occupied by the pores rather than the bulk material. The porosity can vary through the thickness of the layer. For example, the layer may be porous in one or more sublayer. The layer may include an upper portion which is porous with a lower portion that is non-porous. Alternatively the layer may include one or more discrete, non-continuous portions (domains) that are porous with the remainder being non-porous (with bulk material properties). The portions may be non-continuous within the plane of a sublayer and/or through the thickness of the layer (horizontally and/or vertically in the sense of the growth direction). The portions may be distributed in a regular array or irregular pattern across the layer, and/or through it. The porosity may be constant or variable within the porous regions. Where the porosity is variable it may be linearly varied through the thickness, or may be varied according to a different function such as quadratic, logarithmic or a step function.

A fully depleted porous layer means a layer in which there are no charge carriers.

The present invention relates to a light emitting device in which the amount of arsenic (As) is limited so that the devices can be fabricated or further processed in an environment which is sensitive to As. For example, fabrication environments for silicon-based devices must have low levels of As in devices that are processed because As is a dopant for many of the materials usually used. An acceptable level of As can be determined by calculating the As content in each layer and summing for all the layers. The As content in a layer is the product of the concentration of As atoms relative to other group V atoms in the layer and the thickness of the layer. Thus a layer of thickness T, as shown in FIG. 1, with 100% of the group V atoms comprising As will have the same As content as a layer of thickness 2T with only 50% of the group V atoms comprising As. Thus a layer of thickness T which is a binary compound of As and a group III element, such as GaAs, has the same amount of As as a layer of thickness 2T which is a ternary III-V compound where As is 50% of the atomic concentration of the group V elements.

A light emitting device 10 according to the present invention is configured to have a limited concentration of As. Thus it is suitable for fabrication or further processing in an environment which is sensitive to As. For example, the total As content of the light emitting device 10 may be equivalent to less than 20% of the total thickness of the device 10. The total As content can be calculated as the sum product of the As concentration and the layer thickness in each of the layers. That is, the As concentration multiplied by the thickness of a layer, summed for all the layers forming the light emitting device 10.

The light emitting device 10 may be configured to have a lower total As content. For example, 15%, 10%, 5% or 2%. For example, where a device has 200 nm of GaAs as its only As-containing layers, in a device of 1.2 μm total thickness (such as thin LED or edge emitter) the total As content is approximately 17%, whereas in a device of 8 μm total thickness (such as a VCSEL) the total As content is approximately 2.5%. For a thick LED of 4 μm total thickness the As content is approximately 5%. Where the device has 200 nm of InₓGa₁₋ₓAs as its only As-containing layers, and x=0.5, the total As content for a device of 1.2 μm is only approximately 8% and for an 8 μm thick device it is just 1.25%.

The invention will now be described more particularly with reference to FIG. 2 which shows a light emitting diode (LED) 10. The LED 10 comprises a first layer 12 of germanium (Ge). The first layer 12 may be a substrate. The substrate may be Ge that is miscut towards a different major plane. For example, it may be <100> Ge miscut towards the <111> plane although it could be miscut towards a different plane. It may have a large miscut. For example it may be miscut by up to 15°. For example it may be miscut by 6°.

Alternatively it may be a Ge layer formed on another layer or substrate, for example on a silicon (Si) substrate. For example, there may be a Si substrate with a graded composition of SiGe grown on it with a gradually increasing proportion of Ge until the upper layer is pure Ge or mostly Ge, for example 90% Ge and 10% Si, which forms the first layer 12. Thus the first layer 12 may comprise a composition which is substantially Ge, for example where the Ge content is greater than or equal to 90%.

Ge wafers are available in large diameters, 200 mm and 300 mm for example. Advantageously Ge wafers are mechanically robust with low defect levels. This makes Ge particularly suitable for growing LEDs and micro-LEDs where hundreds or thousands of devices are diced from a single wafer and a single defective device may cause an entire product, for example an LED display, to be scrapped. For example a micro-LED device has size on the order of a few micrometres or smaller.

Grown on or over the first layer 12 is a nucleation layer 14. The nucleation layer 14 enables the growth of high quality III-V layers over the Ge first layer 12. It acts as a transition layer to promote the growth of crystalline layers and to smooth the change in lattice constant between the Ge first layer 12 and subsequent layers. The nucleation layer 14 may be thin, a few hundred Angstroms thick for example. The nucleation layer 14 may comprise indium gallium phosphide (InGaP) which can be lattice matched to Ge by appropriate choice of the proportions of In and Ga.

On or over the nucleation layer 14 is a buffer layer 16. The buffer layer 16 restores or improves the surface roughness so that subsequently grown layers have a smooth surface on which to grow. The buffer layer 16 is, preferably, pseudomorphic with respect to the first layer 12 and/or the nucleation layer 14. Alternatively the buffer layer 16 may be metamorphic with respect to the nucleation layer 14. The buffer layer may be doped with Si or another dopant to make it n-type. Alternatively it may be doped with a p-type dopant. Alternatively the buffer layer 16 may be undoped or unintentionally doped. The buffer layer 16 may be relatively thick, for example 100 nm-2 μm. The buffer layer 16 may be formed of a single composition throughout its thickness. For example, it may comprise indium gallium phosphide (InₓGa₁₋ₓP), where x is ˜0.5 so that it is lattice matched to the Ge first layer 12. Alternatively x may be a little greater than or smaller than 0.5, for example 0.45 to 0.55, which introduces a small amount of strain but not enough to stop the buffer layer 16 being pseudomorphic with respect to the first layer 12. Such a range for x would result in strain between about 0.2% tensile and about 0.5% compressive. Advantageously a buffer layer 16 comprising InGaP contains no As and is therefore suitable for processing in a fabrication environment which is sensitive to As such as an environment in which Si-based devices are usually processed. Alternatively the buffer layer 16 may comprise a graded composition in which the proportion of one or more element in the composition increases, decreases or varies through the thickness of the layer. For example the proportion of In may increase as the proportion of Ga decreases or vice versa. The variation in composition may be linear, quadratic, exponential or follow another equation. The variation may be periodic. The proportion of one element may increase and then decrease, or vice versa, through the thickness of the buffer layer 16.

Alternatively the buffer layer 16 may comprise a quaternary compound such as indium gallium aluminium phosphide, In_{y}(GaₓAl₁₋ₓ)_{1-y}P. Advantageously such a buffer layer 16 contains no As and is therefore suitable for processing in a fabrication environment which is sensitive to As such as a Si fabrication environment. Advantageously, for a given In composition y, including Al in the composition has minimal effect on the lattice constant but may improve the optical mode confinement (by changing the refractive index) and carrier confinement in subsequent layers (by changing the bandgap energy) in the buffer layer 16. Thus y may be ˜0.5 to ensure lattice matching to the Ge first layer 12 and x may be chosen to set the desired properties. For example x>0 provides a bandgap energy greater than 1.9 eV, and x>0.5 provides a bandgap energy >2.2 eV.

Alternatively the buffer layer 16 may comprise a quaternary or quinary alloy comprising antimony. For example layer 16 may comprise In_{y}(GaₓAl₁₋ₓ)_{1-y}As_{1-z}Sb_{z}. The binary alloys of Sb (GaSb, InSb, AlSb) have larger lattice constants and lower bandgap energy than the related phosphide (GaP, InP, AlP) and arsenide (GaAs, InAs, AlAs) compounds. Thus the addition of antimony to layer 16 provides an additional degree of freedom for modifying the lattice constant (increasing with increasing z) and the bandgap energy (decreasing with increasing z). For example, layer 16 may contain z>0.1%, or z>1%, or z>10%, up to approximately z<40%, with the Ga/In ratio adjusted to maintain the lattice constant near that of the Ge first layer 12 and nucleation layer 14. The composition of buffer layer 16 may also vary throughout the layer in order to provide a varying profile of lattice constant and band energy or refractive index as a function of thickness.

In an alternative the buffer layer 16 may comprise two or more sublayers as shown in FIG. 3. A first sublayer 18 may be relatively thick and a second sublayer 20 may be relatively thin. For example the first sublayer 18 may be of the order of 200 nm thick in the growth direction and the second sublayer 20 be of the order of 20 nm thick. The first sublayer 18 may comprise InₓGa₁₋ₓP or indium gallium arsenide (InₓGa₁₋ₓAs), where x is approximately 0.5 for InGaP and approximately 0.015 for InGaAs to lattice match to the Ge first layer 12. The second sublayer 20 may comprise gallium arsenide (GaAs). Where the first sublayer 18 comprises InGaP it may be grown under different conditions and/or comprise different proportions of In and Ga compared to the nucleation layer 14. Advantageously by including only a thin layer of GaAs the total As content of the LED 10 is low. Thus the buffer layer 16, and LED 10, is suitable for processing in a fabrication environment where As must be minimised such as an environment in which Si-based devices are usually processed.

Alternatively the second sublayer 20 may be relatively thick and the first sublayer 18 be relatively thin. For example the first sublayer 18 may comprise indium aluminium phosphide (InAlP) with a thickness of around 20 nm and the second sublayer 20 may comprise InGaP with a thickness of 200 nm or more. The second sublayer 20 may be grown under the same or different growth conditions to the nucleation layer 14. It may have the same composition or may have different proportions of In and Ga. Advantageously this combination of sublayer compositions means that the buffer layer 16 comprises no As making it suitable for processing or manufacture in an environment which is sensitive to As.

The first and second sublayers 18, 20 may be arranged so that one has a tensile strain and the other has a compressive strain, which in this case is controlled by the relative proportion of the group III elements within the sublayer. Thus the net strain can be substantially zero meaning that the top surface of the buffer layer 16 is flat. Alternatively the net strain may be arranged to be non-zero so that there is either tensile or compressive strain. This may counteract strain in the first layer 12, for example compressive strain in a SiGe or SiGeSn first layer 12, and/or may pre-strain the structure for the strain to be compensated by subsequent layers of the device 10. Advantageously such net strain may be configured to balance reflectivity with surface roughness. Similarly the first and second sublayers 18, 20 may be arranged to control surface roughness at their interfaces.

On or over the buffer layer 16 is an optional lower mirror 22. The lower mirror 22 comprises alternating pairs of layers with different, high and low, refractive indices. The layers, or certain of them, may be doped with p-type dopants such as beryllium (Be), carbon (C), zinc (Zn) or magnesium (Mg). Alternatively they may be doped with n-type dopants such as Si, selenium (Se), tellurium (Te) or sulphur (S). Alternatively the lower mirror 22 is undoped or unintentionally doped. The layers may comprise InₓAl₁₋ₓP and Inₓ(Al_{y}Ga_{1-y})₁₋ₓP, where x is approximately 0.5 to result in lattice matching to the Ge first layer 12 and y may be chosen to control the bandgap and set appropriate reflectivity contrast, in which case the lower mirror 22 is free of As. For example, the layers may comprise In_{0.5}Al_{0.5}P and In_{0.5}(Al_{0.3}Ga_{0.7})_{0.5}P or In_{0.5}Al_{0.5}P and In_{0.5}(Al_{0.5}Ga_{0.5})_{0.5}P. Alternatively the layers may comprise GaAs and AlₓGa₁₋ₓAs, or GaAs and aluminium arsenide (AlAs), or AlₓGa₁₋ₓAs and AlAs, where x is selected between 0 and 1 and the compound remains lattice matched to Ge. The layers may be the same thickness as each other or the layers of one material may be thicker than the layers of the other material. The doping concentration may be uniform within each layer, or may vary between layers, or may vary within a layer. The thicknesses and/or doping concentrations may be optimised for voltage drop and relative reflectivity, for example. The layers are thicker for longer wavelength devices 10 than for shorter wavelength devices. The thickness of the lower mirror 22 may be arranged so that the total As content of the lower mirror 22, and thus the LED 10, does not exceed a desired amount. Thus the LED 10 can be fabricated in an environment which is sensitive to As. The As content of the lower mirror 22 is a function of the proportion of As in each layer multiplied by the thickness of those layers and summed for all layers which contain As.

The buffer layer 16 may include a transition portion adjacent the nucleation layer 14 which is designed to modify the surface roughness (and lattice constant) of subsequent layers or the interface roughness between pairs of layers above the buffer layer 16, particularly sublayers of the optional lower mirror 22. Such portion may comprise the same material as the nucleation layer 14 but with a different composition and/or grown under different growth conditions. For example it may comprise InGaP. The transition portion may be a few nanometres thick only. By providing this transition portion there may be some decrease in the reflectivity of the optional lower mirror 22, since it has a more similar refractive index to the nucleation layer 14 than the rest of the buffer layer 16, but improves the uniformity of reflectivity across a wafer. Thus the small decrease in reflectivity is counterbalanced by improved device performance and uniformity.

The transition portion of the buffer layer 16 may improve the quantum efficiency or another attribute of the active layer 24 if there is no lower mirror 22.

On or over the optional lower mirror 22 or the buffer layer 16 is an active layer 24. The active layer 24 is arranged to emit light at a desirable wavelength in response to a current across it. The wavelength may be in the range 570 to 1000 nm. For example, the active layer 24 may emit at 570 nm-700 nm which is typical for a red LED. The active layer 24 may be configured as a bulk layer, one or more quantum wells, or one or more quantum dots. The active layer 24 may comprise one layer, or two or more sublayers. For example, it may include quantum wells and quantum barriers in respective sublayers formed of different materials. The active layer 24 may comprise InGaP or InAlGaP, where the In comprises approximately 50% of the group III atomic concentration in order to maintain lattice matching. Advantageously such materials do not contain As. Alternatively the wavelength may be in the range 550 to 620 nm which encompasses orange, amber and green light. Alternatively it may emit at 690 to about 1000 nm which is typical for infrared light. The active layer 24 may comprise InGaAs, GaAs, AlGaAs, or GaAsP for wavelengths between 690 nm and 1000 nm. The active layer 24 is thin, for example about 10 nm to about 500 nm, and therefore the As content is low. For example the active layer 24 may be around 100 nm thick and comprise up to 10 quantum wells for a μLED or up to 300 nm for an edge emitter laser. Alternatively, LED 10 may also have a much thicker bulk active layer 24, for example around 500 nm. However, the active layer 24 is still thin relative to the total thickness of the LED 10 and therefore the As content is low. Advantageously, therefore, the As in the active layer 24 does not exceed the total As content which is acceptable in the LED 10.

Optionally there may be a lower cladding layer 26 between the lower mirror 22 and the active layer 24. The lower cladding layer 26 provides confinement of the optical mode. It may also confine charge carriers, holes where the lower mirror 22 is n-type doped, in the active layer 24. It may also function as a carrier injection layer. In this case it is configured as an intracavity contact. The lower cladding layer 26 may comprise InAlP or InAlGaP as is typical for red emitters. Advantageously the lower cladding layer 26 does not include any As. The lower cladding layer 26 may comprise sublayers having different compositions and/or doping concentration and/or thickness, for example to accommodate mode expansion.

Optionally there may be an upper cladding layer 28 on or over the active layer 24. The upper cladding layer 28 provides confinement of the optical mode. It may also confine charge carriers, electrons or holes depending on the configuration of the light emitting device, in the active layer 24. It may also function as a carrier injection layer and be configured as an intracavity contact. The upper cladding layer 28 may comprise the same material as the lower cladding layer 26 or may comprise a different material or a different composition of the same material. It may comprise InAlP or InAlGaP. Advantageously the upper cladding layer 28 does not include any As. The upper cladding layer 28 may comprise sublayers having different compositions and/or doping concentration and/or thickness, for example to accommodate mode expansion.

Optionally an upper mirror 30 is provided on or over the active layer 24. Where an upper cladding layer 28 is present the upper mirror 30 is provided on or over the upper cladding layer 28. The upper mirror 30 may be an epitaxially grown mirror comprising alternating pairs of layers with different, higher and lower, refractive indices. The layers forming the upper mirror 30 may be doped. Where the lower mirror 22 is doped with n-type dopants the upper mirror 30 may be doped with p-type dopants such as Be, C, Mg or Zn. Where the lower mirror 22 is doped with p-type dopants the upper mirror 30 may be doped with n-type dopants such as Si, Se, Te or S. Alternatively the upper mirror 30 is undoped or unintentionally doped. The upper mirror 30 may comprise alternating layers of InₓAl₁₋ₓP and Inₓ(Al_{y}Ga_{1-y})₁₋ₓP, where x is approximately 0.5 for lattice matching and y is chosen to control the bandgap and set the relative refractive indices. In this case the upper mirror 30 contains no As. The upper mirror 30 may comprise alternating layers of GaAs and AlₓGa₁₋ₓAs, or of GaAs and AlAs, or of AlₓGa₁₋ₓAs and AlAs. In this case x is chosen between 0 and 1 based on the desired bandgap and refractive index. AlₓGa₁₋ₓAs with x=0.605 is lattice matched to Ge, although the strain generated by compounds with a different x are typically small. The upper mirror 30 may have the same layer materials as the lower mirror 22. The composition of each layer may be the same as the lower mirror 22 or may differ. Alternatively the upper mirror 30 may comprise a different material set to the lower mirror 22. The layer thicknesses may be the same as the lower mirror 22 or may be different. Where the upper mirror includes As the thickness and composition of the layers is controlled so that the total As content of the LED 10 does not exceed a desired value. The upper mirror 30 may have a different number of layer pairs than the lower mirror 22, typically fewer pairs for a front emitting LED. For example, the lower mirror 22 may comprise 26.5 layer pairs and the upper mirror 30 may comprise 5 layer pairs, which results in reflectivity close to 100%. Alternatively the lower mirror 22 may comprise 10 pairs and the upper mirror 30 may comprise 4 pairs which gives a lower voltage drop albeit with less focused emission.

Alternatively the upper mirror 30 may be a dielectric mirror which is provided on or over the active layer 24 or upper cladding layer 28. Since a dielectric mirror is not doped the upper cladding layer 28 is required to inject charge carriers into the structure to generate a current across the active layer 24 in operation. The dielectric upper mirror 30 may be bonded to the lower layers. Alternatively a bulk material may be grown and then be porosified to produce sublayers of higher and lower refractive index.

The optional lower and upper cladding layers 26, 28 may also act to space the optional lower mirror 22 and upper mirror 30 at an optimum distance from each other. The optional lower and upper cladding layers 26, 28 may form an optical cavity to provide overlap between the active layer 24 and the optical mode defined by the optional lower and upper mirrors 22, 30.

Optionally a cap layer 32 may be grown or provided on or over the optional upper mirror 30, optional upper cladding layer 28 or active layer 24. The cap layer 32 may be highly doped in order to enable a low contact resistance electrode to be provided above the active layer 24.

Where the lower cladding layer 26 is omitted or is not configured as an intracavity contact there may be a lower contact 34 which is attached to the substrate or first layer 12. The lower contact 34 may be attached to the rear of the substrate or first layer 12, as illustrated in FIG. 2. Alternatively the lower contact 34 may be attached to the front of the substrate or first layer 12. Alternatively it may be attached to the lower mirror 22. Where the lower cladding layer 26 is provided the lower contact 34 may instead be attached to the lower cladding layer 26. In this case the lower mirror 22 can be undoped or unintentionally doped.

There may be an upper contact 36 provided at the top of the LED 10. It may be attached to the optional cap layer 32, as illustrated in FIG. 2, or to the top of the optional upper mirror 30. The upper contact 36 may include an aperture to direct and/or focus the emitted light. Alternatively the upper contact 36 may take the form of a grid in order to allow the light to be emitted in a predefined pattern. The upper contact 36 may be attached to the upper cladding layer 28 where that is provided, in which case the upper mirror 30 need not be doped and can be a dielectric mirror instead of an epitaxially grown mirror.

The lattice mismatch between adjacent layers may be controlled so that a specific wafer shape is obtained. For example, the lattice mismatch can be controlled such that the wafer is flat. This is advantageous because subsequently grown layers are grown on a flat surface and they are deposited in a uniform thickness with uniform properties. It also means that the heat, from the heated holder that supports the substrate in an epitaxy reactor, is distributed evenly across the wafer and so the subsequently grown layers experience the same heating across them and therefore grow more uniformly. Alternatively the lattice mismatch can be controlled so that it introduces some strain in one or other direction so that the wafer becomes slightly convex or concave. Advantageously this can provide pre-strain which is relaxed when the LED 10 wafer is removed from the epitaxy reactor and cooled to operational temperature. Additionally or alternatively it can provide a desirable wafer shape to match existing processes and equipment.

There may be an optional window layer 38 (also known as a current-spreading layer), as shown in FIG. 4. The window layer 38 improves the spreading of charge carriers from the optional upper contact 36 to the active layer 24. The window layer 38 may also improve light extraction. In a front emitting LED 10 the window layer 38 is positioned above the active layer 24, adjacent to and beneath the optional cap layer 32. The window layer 38 may be relatively thick, for example up to 3 μm thick, up to 10 μm, or up to 20 μm. It comprises a material which has a wider bandgap than the active layer 24. For example, it may comprise InAlGaP or AlP. Advantageously such a window layer 38 does not include any As and is therefore suitable for a device fabricated in an environment which is sensitive to As. The window layer 38 may alternatively comprise GaAs or AlGaAs with the thickness limited to maintain the level of As below the desired threshold to enable fabrication in an As sensitive environment.

FIG. 5 illustrates an LED 10 in which there are no upper or lower mirrors 30, 22. Instead the upper and lower cladding layers 28, 26 are thicker in order to adequately space the buffer 16, active layer 24 and window layer 38. Alternatively the lower mirror 22 may be omitted in favour of a thicker lower cladding layer 26 and the upper mirror 30 be retained. Alternatively the upper mirror 30 may be omitted in favour of a thicker upper cladding layer 28 and the lower mirror 22 be retained. Each of the variants described above is also applicable to this arrangement. For example, the buffer layer 16 may comprise two sublayers 18, 20; there may be an optional cap layer 32; and the upper and lower contacts 36, 34 may be attached to any suitable part of the device 10.

Although the device 10 has been described as an LED it could alternatively be a combined LED and photodetector, as illustrated in FIG. 6. Above the Ge first layer 12 and buffer layer 16 is the photodetector, which is a PIN photodetector 40 as illustrated. The PIN photodetector 40 comprises a first layer 42, a second layer 44 and an intrinsic absorber layer 46 between them. The first and second layers 42, 44 are oppositely doped, thus one is n-doped and the other is p-doped. For example the first layer 42 may be n-doped and the second layer 44 be p-doped. The absorber layer 46 is undoped or unintentionally doped. When a photon hits the absorber layer 46 it creates an electron-hole pair which therefore creates a detectable current between the first and second layers 42, 44. The absorber layer 46 composition is chosen such that its bandgap energy is slightly lower than the energy of the photons produced by the active region. The composition of the first layer 42 and second layer 44 are chosen such that their bandgap energy is higher than the energy of the photons produced by the active region, to minimize photon absorption in the doped layers. In common with other photodetectors the PIN photodetector 40 is reverse-biased, meaning the current increases when photons of the desired wavelength are absorbed.

The PIN photodetector 40 can be designed to absorb (detect) light with a longer wavelength than is emitted from the LED 10. Therefore the absorber layer 46 may comprise the same material as the active layer 24 of the LED 10, with a smaller bandgap energy, for example InGaAlP with less Al. Alternatively it may comprise a different material with a smaller bandgap energy, for example AlGaAs provided the total arsenic content is not exceeded. Thus for red light (approximately 570-700 nm) the absorber layer 46 comprises InGaP or InAlGaP, where the In comprises approximately 50% of the group III atomic concentration. The first and second layers 42, 44 comprise a higher bandgap material, with different doping, so that they do not absorb light emitted by the LED 10, in the same way that the cladding layers 26, 28 of the LED 10 have a higher bandgap than the active layer 24.

Above the PIN photodetector 40 is the LED or resonant cavity LED 10 as described above. Thus there is a buffer layer 16, which may comprise sublayers 18, 20, followed by optional lower mirror 22, optional lower cladding layer 26, active layer 24, optional upper cladding layer 28, optional upper mirror 30 and optional cap 32. Each device comprises two contacts, of which one is typically common. Thus there may be a lower contact 34 attached to the top or rear of the first layer 12 or to the first layer 42 of the PIN photodetector 40. There may be an upper contact 36 attached to the top of the cap layer 32, upper mirror 30, upper cladding layer 28 or active layer 24. There may be a middle contact 48 attached to the second layer 44 of the PIN photodetector 40, as shown in FIG. 6. The contacts 34, 36 may be arranged as intracavity contacts embedded in the layer stack.

Alternatively the PIN photodetector 40 may be positioned intermediate the optional lower mirror 22. That is that one, two or more sublayers of the lower mirror 22 are grown then the first layer 42, absorber layer 46 and second layer 44 of the PIN photodetector 40 are grown, and then the rest of the sublayers of the lower mirror 22 are grown over them.

Alternatively the PIN photodetector 40 may be positioned above the active layer 24, for example between the active layer 24 and the upper mirror 30, as shown in FIG. 7. Alternatively the PIN photodetector 40 may be positioned intermediate the optional upper mirror 30. That is that one, two or more sublayers of the upper mirror 30 are grown then the first layer 42, intrinsic layer 46 and second layer 44 of the PIN photodetector 40 are grown, and then the rest of the sublayers of the upper mirror 30 are grown over them.

The LED 10 may include a tunnel junction so that the optional upper mirror 30 and lower mirror 22 have the same dopant type, for example both p-type or both n-type. The tunnel junction may be grown adjacent to one of the lower and upper cladding layers 26, 28.

Although the device 10 has been described as an LED it could alternatively be an edge emitting laser. In this case the optional lower mirror 22 or optional upper mirror 30 may be omitted and the lower and upper cladding layers 26, 28 may form a waveguide to assist optical mode propagation in the in-plane direction. The lower and upper cladding layers 26, 28 may comprise sub-layers. The active layer 24 may also or alternatively comprise sub-layers.

Although the device 10 has been described as an LED it could alternatively be a vertical cavity surface emitting laser (VCSEL). In this case the lower mirror 22 and upper mirror 30 are necessary and may have more layer pairs than in an LED. The lower mirror 22 may comprise alternating layers of GaAs and AlAs or GaAs and AlₓGa₁₋ₓAs which results in a low strain mirror when grown over a Ge first layer 12. The As content may be controlled, and/or the number of layer pairs restricted, so that the total As content of the VCSEL does not exceed the desired level. The active layer 24 also includes an oxidation layer which includes an aperture for the emission of the light vertically.

The layers of the device 10 may be grown epitaxially in an MOCVD reactor. Alternatively they may be grown in an MBE reactor or by any other epitaxial process. Alternatively the layers may be grown or deposited by another deposition method. Some of the layers may be provided by other means such as bonding.

1. A resonant cavity light emitting device comprising:
a substantially germanium first layer;
a nucleation layer;
a buffer layer comprising a III-V composition; and
an active layer (24),
wherein a sum product of arsenic concentration and layer thickness in each of the layers is less than 20% of the total thickness of the device.

2. The light emitting device of claim 1, wherein the light emitting device is configured to emit light with a wavelength between 570 nm and 1000 nm.

3. The light emitting device of claim 1, wherein the sum product is less than 15%, less than 10%, less than 5%, or less than 2%.

4. The light emitting device of claim 1, wherein;
the buffer layer comprises a first sublayer adjacent the nucleation layer and a second sublayer,
the first sublayer comprises a III-V composition, and
the second sublayer comprises a different III-V composition.

5. The light emitting device of claim 1, wherein;
the buffer layer comprises a first sublayer adjacent the nucleation layer and a second sublayer, and
the first sublayer and second sublayer of the buffer layer comprise the same material, the same composition, or both.

6. The light emitting device of claim 4, wherein the first sublayer comprises indium gallium phosphide, indium aluminium phosphide, or indium gallium arsenide.

7. The light emitting device of claim 4, wherein the second sublayer comprises gallium arsenide or indium gallium phosphide.

8. The light emitting device of claim 1, further comprising a lower mirror, wherein the lower mirror comprises a III-V material composition without arsenic.

9. The light emitting device of claim 8, wherein the lower mirror comprises an alternating stack of indium aluminium phosphide and indium aluminium gallium phosphide sublayers.

10. The light emitting device of claim 1, further comprising a lower cladding layer between the substantially germanium first layer and the active layer.

11. The light emitting device of claim 1, further comprising an upper mirror.

12. The light emitting device of claim 11, wherein the upper mirror comprises an alternating stack of indium aluminium phosphide and indium aluminium gallium phosphide sublayers.

13. The light emitting device of claim 11, further comprising an upper cladding layer between the active layer and the upper mirror, wherein the upper cladding layer comprises indium gallium phosphide or indium gallium aluminium phosphide.

14. (canceled)

15. The light emitting device of claim 1, wherein the active layer comprises indium gallium phosphide or indium gallium aluminium phosphide.

16. The light emitting device of claim 1, wherein the substantially germanium first layer comprises germanium with a large miscut.

17. The light emitting device of claim 1, wherein the substantially germanium first layer is a substrate miscut by up to 15° from a major crystal plane.

18. The light emitting device of claim 1, wherein the nucleation layer comprises indium gallium phosphide.

19. The light emitting device of claim 1, wherein the buffer layer is doped.

20. (canceled)

21. A method of fabricating a resonant cavity light emitting device comprising steps to:
grow a nucleation layer on a substantially germanium first layer;
grow a buffer layer on the nucleation layer; and
grow an active layer,
wherein there is less than 20% As in the light emitting device, of the total thickness of the device, calculated as the sum product of the As concentration in a layer and the thickness of the layer.

22. The method of fabricating the light emitting device of claim 21, wherein the steps comprise growing layers using metal-organic vapour phase epitaxy, metal-organic chemical vapour deposition, or molecular beam epitaxy.
